(19) United States
(12) Patent Application Publication
(10) Pub. No.: US 2025/0235815 A1
(43) Pub. Date: Jul. 24, 2025

(54) WET PROCESS AIR ABATEMENT SYSTEM AND METHOD

(71) Applicant: Taiwan Semiconductor Manufacturing Company Ltd., Hsinchu (TW)

(72) Inventors: Chih-Ming Tsao, Hsinchu (TW); Chieh-Pu Lai, Hsinchu (TW)

(21) Appl. No.: 18/417,152

(22) Filed: Jan. 19, 2024

(51) Int. Cl. B01D 53/18; B01D 53/14; B01D 53/34; B01D 53/54; B01D 53/79; H01L 21/67

(52) U.S. Cl. CPC B01D 53/185; B01D 53/1412; B01D 53/346; B01D 53/54; B01D 53/79; B01D 2257/40; B01D 2258/0216; H01L 21/67017

(57) ABSTRACT

A method includes: processing a wafer by a wet bench apparatus; forming particulates in an exhaust of the wet bench apparatus; flowing the exhaust to a first scrubbing chamber of a scrubber; removing a first portion of the particulates from the exhaust by flowing the exhaust to a second scrubbing chamber via a structured packing material; cooling the second scrubbing chamber by a vortex tube; and removing a second portion of the particulates from the exhaust by a structured demister adjacent the second scrubbing chamber.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagrammatic view of a semiconductor processing system with cleaning system according to embodiments of the present disclosure.

FIG. 2 is a process flow view illustrating formation of salt particulates according to various aspects of the present disclosure.

FIG. 3 is a diagrammatic view of a cleaning system having structured packing, structured demisting and a vortex tube according to various aspects of the present disclosure.

FIG. 4 is a diagrammatic view of a vortex tube in accordance with various embodiments.

FIG. 5 is a process flow view illustrating nucleation and capture of salt particulates in accordance with various embodiments.

FIGS. 6A, 6B, 6C are diagrammatic views of a cleaning system and structured packing thereof in accordance with various embodiments.

FIG. 7 is a diagrammatic view of a semiconductor processing system in accordance with various embodiments.

FIG. 8 is a schematic view of a controller in accordance with various embodiments.

FIG. 9 is a diagrammatic view of a sampling system in accordance with various embodiments.

FIG. 10 is a flowchart of a method of performing semiconductor processing in accordance with various embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Terms such as “about,” “roughly,” “substantially,” and the like may be used herein for ease of description. A person having ordinary skill in the art will be able to understand and derive meanings for such terms.

Semiconductor fabrication generally involves the formation of electronic circuits by performing multiple depositions, etchings, cleanings, annealings and/or implantations of material layers, whereby a stack structure including many semiconductor devices and interconnects between is formed. Some etching and/or cleaning operations are performed by a wet bench apparatus. For example, a wet bench apparatus may include one or more chemical baths or tanks, temperature-controlled baths, agitation systems, spray systems, megasonic or ultrasonic cleaning systems, rinsers, dryers and the like.

Environmental regulations are stricter as regards ammonium salt emission control. For example, sulfuric acid (H₂SO₄) discharge from an exhaust stack may be regulated to be no more than a few tons per year. Acid and base liquids can act simultaneously to form ammonium salts in a wet process (bench) simultaneously, and such tiny particles may be hard to removal by liquid entirely in a wet-type local scrubber (LSC) downstream of bench exhaust. When LSCs for a bench tool struggle to improve ammonium salt removal, emission exhaust may exceed EIA regulations, which may result in a fab shutdown by local government.

The wet clean tool may run a recipe that performs acidic and basic reactions in different chambers, such that sulfuric acid (H₂SO₄) and ammonia (NH₄OH) are exhausted simultaneously, which can induce neutralized salts, such as ammonium sulfate (NH₄)₂SO₄. Measurement data indicates that ammonium sulfate is in the form of solid particles (or “particulate matter” or “PM”). However, particle sizes of (NH₄)₂SO₄ can be in a range of about 0.1 micrometers (um) to about 1 um (or “PM1”), which is too small to be removed. The measurement data indicates that (NH₄)₂SO₄ removal efficiency is only about 40%-55% in current in-situ local scrubbers and filters.

When a wet-type local scrubber is applied for bench exhaust treatment, although a scrubbing liquid (e.g., water) can absorb gaseous acid or alkaline, absorption performance for particles (<1 um) is poor. A wet scrubber may use random packing as a mass transfer media to enhance gaseous pollutant absorption into liquid. However, the random packing may not be suitable for particle matter removal, causing LSC particle removal performance to be poor for total acid. For example, total acid removal efficiency for existing scrubbers may only reach 40%-70%. The wet-type local scrubber may include a chevron-type demister for removing water mist by inertial force and collision of mist when flue gas passes through a twisting pathway. However, the removal efficiency of the demister is poor when water mist droplet size is smaller than 1 um. Existing wet-type local scrubbers may also lack adaptive capability for capacity control, so that once the bench tool exhaust emission level changes, unnecessary utility resources (e.g., water and electricity) are wasted.

In embodiments of the disclosure, structured packing having higher interfacial area (>250 m²/m³) is included instead of random packing, which can enhance mass transfer performance and treat most gas/solid compounds simultaneously. A vortex tube is included, which produces cold air as a coolant in rear of packing to decrease air flow temperature to below a dew point to condense water mist to water droplets. Dissolved ammonium salt in the water droplets may be removed with condensate water. The smallest droplet diameter can be controlled to be no less than 3 um. A structured demister instead of a chevron or random packing type demister improves condensate water removal and drain out of dissolved ammonium salt.

In embodiments of the disclosure, an inline acid and/or alkaline sensor may be installed to sample discharge of the local scrubber to measure acid/alkaline matter and relevant ammonium salt concentration. Once acid/alkaline matter and relevant ammonium salt concentration in discharge changes, the sensor can send back a signal to a management system, and control compressed air (CDA) flow rate and/or cold air discharge temperature of the vortex tube, which may be selected locally or centrally, manually or remotely. The management system can collect tool status data from a fault detection system (FDC) and select opening of a CDA control valve into the vortex tube according to the quantity of wafer throughput and chemical consumption of the bench tool. The management system can compare the tool status data with data received from the acid/alkaline sensor, and according to an algorithm in the management system, select a cold air flow rate into local scrubber autonomously to improve particulate removal. Cleaning systems having the structured packing, structured demister, vortex tube and control system can have increased ammonium salt particulate removal, which can prolong intervals between preventative maintenance and reduce tool downtime.

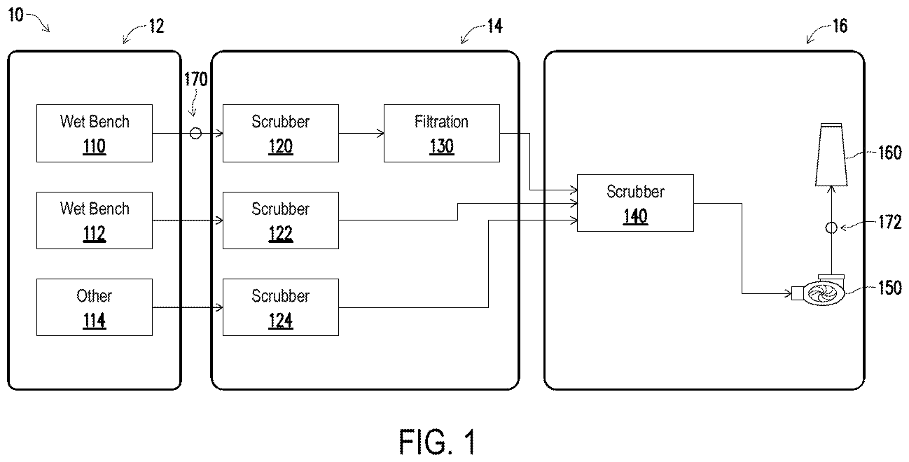

FIG. 1 is a diagrammatic view of a semiconductor processing system 10 with cleaning system 14 according to embodiments of the present disclosure. The semiconductor processing system 10 may include semiconductor processing apparatuses 12, a local cleaning system 14 and a central cleaning and exhausting system 16.

The semiconductor processing apparatuses 12 may include one or more wet bench apparatuses 110, 112, other processing apparatuses 114 and the like.

A first wet bench apparatus 110 may perform a sulfuric peroxide mix (SPM) cleaning operation followed by a standard clean (SC-1) or “hot ammonium hydroxide-hydrogen peroxide mixture” (APM) cleaning operation. Because the SPM cleaning is acidic and the SC-1/APM cleaning operation is basic or alkaline, and the operations are performed simultaneously in different chambers of the first wet bench apparatus 110, exhaust of the first wet bench apparatus 110 that includes exhaust of both cleaning processes may have ammonium salt particulates therein. The first wet bench apparatus 110 may have an outlet that is in communication with an inlet of a first scrubber 120 of the local cleaning system 14. The exhaust including particulates may be introduced to the first scrubber 120 via the inlet.

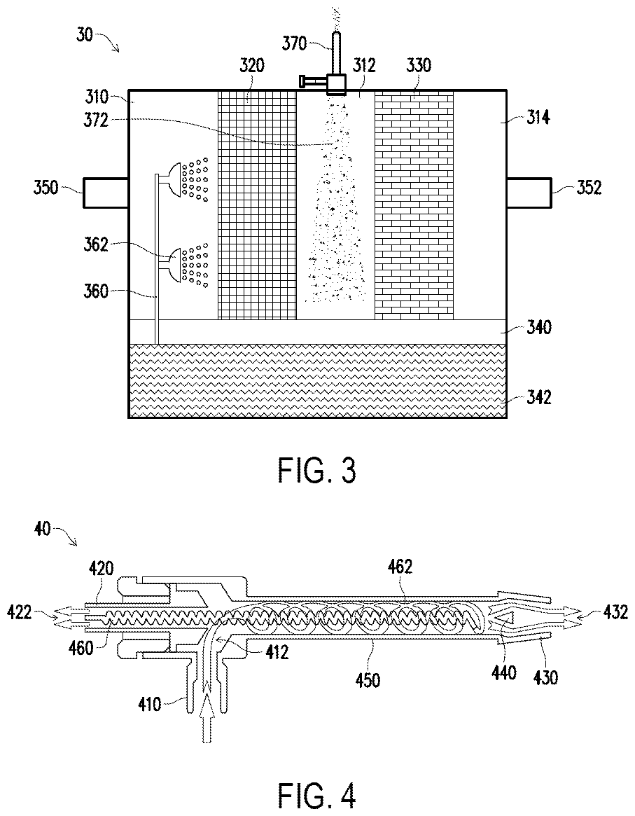

The first scrubber 120 may be a wet-type scrubber that is operable to clean the incoming exhaust, for example, by removing sulfuric acid and ammonia from the exhaust. The first scrubber 120 has improved ability to remove ammonium salt particulates from the exhaust of the first wet bench apparatus 110. Detailed structure and operation of the first scrubber 120 are described with reference to FIGS. 3-5 below.

The first scrubber 120 may output scrubber exhaust to a filtration system 130, which may be or include a serial deep-cleaning filter. The filtration system 130 may include one or more pumps and filters that operate together to pass the scrubber exhaust through the filters, thereby removing remaining contaminants (e.g., process gases) and/or particulates from the scrubber exhaust. The filtration system 130 may output filtration exhaust to the central cleaning and exhausting system 16.

A scrubber 140 may receive the filtration exhaust and perform an additional wet-type scrubbing operation on the filtration exhaust to further remove contaminants and/or particulates from the filtration exhaust. Then, the scrubber 140 may output central scrubber exhaust to a fan 150.

The fan 150 may be an industrial fan and/or pump that draws the central scrubber exhaust from the scrubber 140 to an exhaust vent or stack 160.

The central scrubber exhaust exits the fan 150 and is released into the external environment (e.g., the atmosphere) via the stack 160, which may be a chimney or other appropriate exhausting structure.

Some wet bench tools 112 and/or other processing tools 114 may omit the filtration system 130. For example, a wet bench tool 112 that performs semiconductor processing using high-temperature H₂SO₄ and/or Caro's acid. For example, the wet bench tool 112 may perform particle removal, organic residue removal, metal and/or silicon nitride etching, surface oxidation, post-CMP (chemical mechanical planarization) cleaning, or the like.

A scrubber 122 that is similar to the scrubber 120 in most or all respects may clean exhaust from the wet bench tool 112. Scrubber exhaust generated by the scrubber 122 may pass directly to the scrubber 140 without additional filtration by the filtration system 130 or a similar, separate filtration system. The scrubber 140 may directly scrub the scrubber exhaust of the scrubber 122, then the central scrubber exhaust of the scrubber 140 may pass to the atmosphere via the fan 150 and the stack 160.

The other processing tools 114 may similarly generate exhaust that is scrubbed by a scrubber 124. The scrubber 124 may be similar in many respects to the scrubbers 120, 122, but may differ in some respects therefrom, as well. Scrubber exhaust from the scrubber 124 may pass directly to the scrubber 140 without additional filtration by the filtration system 130 or a similar, separate filtration system. The scrubber 140 may directly scrub the scrubber exhaust of the scrubber 124, then the central scrubber exhaust of the scrubber 140 may pass to the atmosphere via the fan 150 and the stack 160.

In the system 10 and process depicted and described with reference to FIG. 1, efficiency of removal of particulates (e.g., the ammonium salt particulates) from the exhaust of the wet bench 110 prior to release via the stack 160 may be determined by measuring particulate levels at a first point 170 between the wet bench 110 and the scrubber 120 and at a second point 172 between the fan 150 and the stack 160. The inventors have found that, without inclusion of a vortex tube and structured packing and/or demisters, efficiency of particulate removal is in a range of about 45% to about 55%. Inclusion of the structured packing and/or demister can increase the efficiency to a range of about 60% to about 75%, or more. In some cases, efficiency has been measured at more than 89%. The increased efficiency results in dramatically reduced tool downtime due to preventative maintenance, as period between preventative maintenance cycles can be prolonged due to reduction in contaminants and particulates.

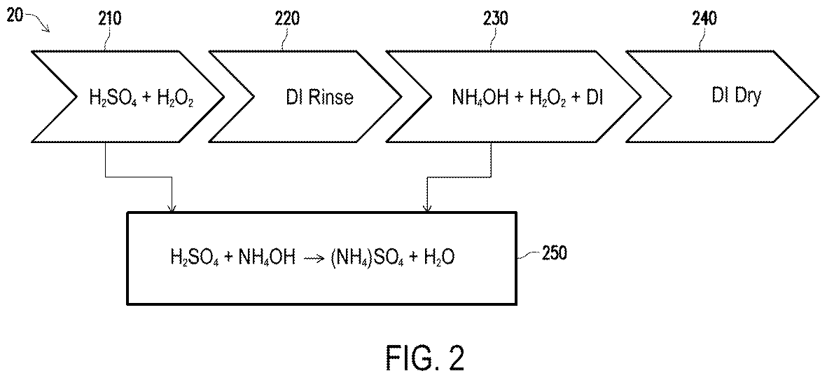

FIG. 2 is a process flow view illustrating formation of salt particulates according to various aspects of the present disclosure. As described with reference to FIG. 1, the wet bench 110 may perform an SPM cleaning operation 210 simultaneously with an APM cleaning operation 230. A rinse operation 220 and a dry operation 240 may be performed after the SPM cleaning operation 210 and the APM cleaning operation 240, respectively. Although the cleaning operations 210, 230 are performed in sequence as regards a single wafer, when a first wafer is undergoing the APM cleaning operation 230, a second wafer may be undergoing the SPC cleaning operation simultaneously, albeit in a different chamber. The different chambers associated with the respective cleaning operations exhaust different process gases, such as H₂SO₄ and NH₄OH, to the local scrubber 120. For example, the exhausted process gases may undergo mixing 250 in a commonly shared transport line prior to reaching the local scrubber 120.

As depicted in FIG. 2, the mixing 250 may be according to H₂SO₄+NH₄OH→(NH₄)₂SO₄+H₂O, which results in a particulate byproduct (NH₄)₂SO₄, also referred to as ammonium sulfate, which is an ammonium salt.

It should be understood that, although the embodiments are described with reference to ammonium salt (e.g., ammonium sulfate) formed by mixing exhaust of a wet bench tool, the embodiments are not limited thereto. For example, particulates other than ammonium salt may be exhausted by the wet bench tool 110 and removed with improved efficiency by the wet-type scrubber 120. A different wet bench tool than the wet bench tool 110 may exhaust ammonium salt. A processing tool other than the wet bench tool 110, such as a furnace or other processing tool, may exhaust other particulates that can be removed with improved efficiency by the wet-type scrubber 120. Namely, the wet-type scrubber 120 described and broadly embodied herein may be operable to remove particulates including ammonium salt and other than ammonium salt with improved efficiency due to inclusion of the structured packing, structured demisting, the vortex tube, or combinations thereof.

FIG. 3 is a diagrammatic view of a cleaning system or air abatement system 30 having structured packing 320, structured demisting 330 and a vortex tube 370 according to various aspects of the present disclosure. The cleaning system 30 may be an embodiment of the scrubber 120 of FIG. 1.

The cleaning or scrubber system 30 may include a first scrubbing chamber 310, a second scrubbing chamber 312 and a third scrubbing chamber 314. The first and second scrubbing chambers 310, 312 may be separated by a packing material 320. The second and third scrubbing chambers 312, 314 may be separated by a demister 330. The cleaning system 30 may have one or more inlets 350 and one or more outlets 352. The cleaning system 30 includes a sump or bath 340 having scrubbing liquid 342 therein. The cleaning system 30 may include a recirculation system 360 including one or more sprayers 362. The cleaning system 30 includes a vortex tube 370 that outputs cooled air 372 into the second scrubbing chamber 312.

The inlet or inlet duct 350 is where contaminated gas from a wet bench tool (e.g., the wet bench tool 110) enters the scrubber system 30. Contaminated gas may enter the scrubber system 30 via the inlet duct 350, which may include a single inlet duct 350 as depicted or multiple inlet ducts 350, such as two, three, four or more inlet ducts.

The scrubbing chambers 310, 312 are areas where scrubbing takes place. For example, the gas entering the scrubber system 30 from the inlet 350 comes in contact with the scrubbing liquid 342 in the first and second scrubbing chambers 310, 312. The scrubbing liquid 342 in the first and second scrubbing chambers 310, 312 may be in a mist form. Temperature in the first scrubbing chamber 310 may be higher than that in the second scrubbing chamber 312 due to action of the vortex tube 370 in the second scrubbing chamber 312.

The spray nozzles 362 may be situated above the scrubbing chambers 310, 312 or may be distributed throughout various positions in the scrubbing chambers 310, 312. Scrubbing liquid 342 is sprayed onto the incoming gas stream through spray nozzles 362 to initiate the scrubbing process in the first scrubbing chamber 310. The spray nozzles 362 spray the scrubbing liquid 342, which may be a liquid absorbent or solvent, to mix with the gas that comes in through the inlet 350 and/or through the packing material 320.

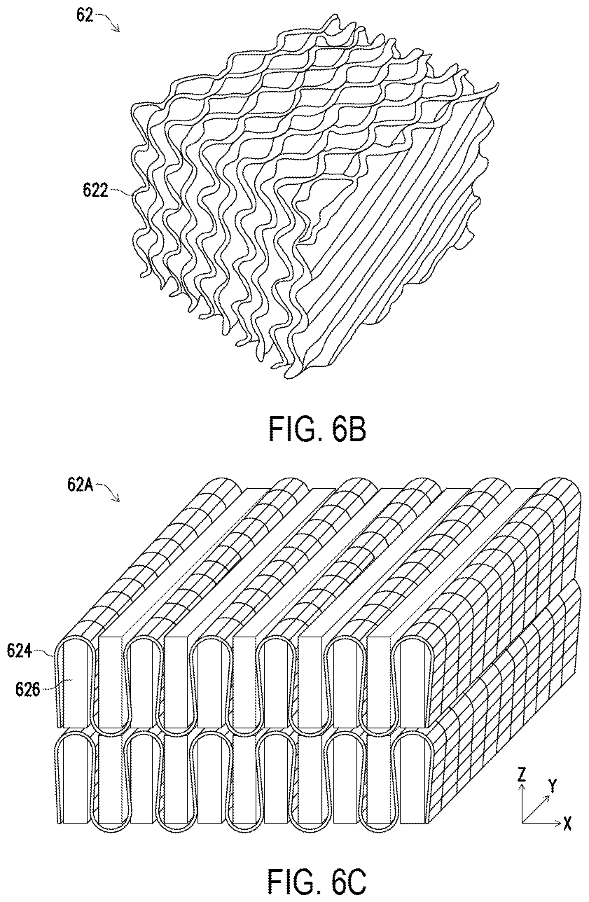

The packing material 320 may fill (entirely or partially) an area between the first scrubbing chamber 310 and the second scrubbing chamber 312. The gas flows through the section filled with the packing material 320, which is beneficial to increase surface area for interaction, facilitating better contact between the gas and the scrubbing liquid 342. The packing material 320 may remove a first portion of particulates from the exhaust transiting therethrough. The packing material may be made of various substances, such as plastic or ceramic, which may be beneficial for chemical compatibility with the gas and/or scrubbing liquid 342 and efficiency of removing contaminants and particulates. The packing material can increase surface area which is beneficial for increasing gas-liquid contact, for example, between the exhaust gas that enters the scrubber 30 and the scrubbing liquid 342 dispensed by the spray nozzles 362. In some embodiments, the packing material 320 is a structured packing material that has interfacial area that exceeds about 250 m²/m³, such as about 300 m²/m³. The packing material 320 being “structured” may include the meaning that the packing material 320 has a repeating, regular and/or uniform structural pattern and/or distribution instead of a random pattern and/or distribution. The increased interfacial area (e.g., >250 m²/m³) instead of random packing is beneficial to increase mass transfer performance and treat most gas/solid compounds simultaneously. Embodiments of the packing material 320 are described in greater detail with reference to FIGS. 6B and 6C.

In some embodiments, while passing through the packing material section 320, chemical reactions may occur between the contaminants in the gas and the scrubbing liquid 342. This can be beneficial to neutralize or absorb the pollutants and/or particulates more effectively. In some embodiments, additional scrubbing liquid 342 may be sprayed above or within the packing material 320 to maintain adequate wetting and improve scrubbing efficiency.

The eliminator or demister 330 is positioned before the outlet 352 between the second scrubbing chamber 312 and the third scrubbing chamber 314 and removes droplets of scrubbing liquid 342. After passing through the packing material 320, the gas moves into the second scrubbing chamber 312, then to the eliminator or demister section 330, which can remove remaining liquid droplets from the cleaned gas. Namely, the demister 330 may remove a second portion of particulates from the exhaust transiting therethrough. In the second scrubbing chamber 312, additional scrubbing liquid 342 may be sprayed into the chamber area to increase droplet size and improve capture of particulates prior to passing through the demister 330. In some embodiments, the demister 330 is a structured demister that has interfacial area that exceeds about 250 m²/m³, such as about 300 m²/m³. The demister 330 being “structured” may include the meaning that the demister 330 has a repeating, regular and/or uniform structural pattern and/or distribution instead of a random pattern and/or distribution. The increased interfacial area (e.g., >250 m²/m³) instead of random packing is beneficial to increase mass transfer performance and treat most gas/solid compounds simultaneously. Embodiments of the demister 330 are described in greater detail with reference to FIG. 6C.

The outlet duct 352 is in communication with the third scrubbing chamber 314, and the cleaned gas is expelled from the outlet duct 352. In some embodiments, the cleaned gas is released to a filtration system (e.g., the filtration system 130), another scrubber (e.g., the central scrubber 140) or to an exhaust stack (e.g., the stack 160) via the outlet duct 352.

The sump 340 may be positioned at a bottom of the scrubber system 30 where spent scrubbing liquid 342 can collect. In some embodiments, the spent scrubbing liquid 342 that collects in the sump 340 is treated and recirculated and/or is removed for waste treatment. The spent scrubbing liquid 342 may enter the sump 340 via gravitational force acting on scrubbing liquid 342 that collects on and/or in the packing material 320 and on and/or in the demister 330.

The recirculation system 360 circulates the scrubbing liquid 342 from the sump 340 back to the spray nozzles 362. The recirculation system 360 may include one or more pumps, transport lines and spray nozzles 362. The pump may pump scrubbing liquid 342 in the sump 340 to the transport lines, and pressure from the pump may cause the scrubbing liquid 342 in the transport lines to exit the recirculation system 360 via the spray nozzles 362 into the first and/or second scrubbing chambers 310, 312, the packing material 320, the demister 330, or a combination thereof.

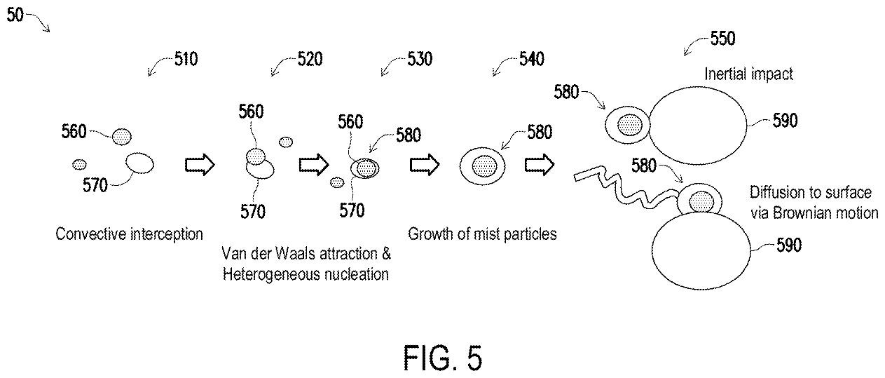

The cleaning system 30 includes a vortex tube 370 that is in communication with the second scrubbing chamber 312. The vortex tube 370 is operable to output cooled air and heated air based on compressed air. Detailed structure and operation of an embodiment of the vortex tube 370 are described with reference to FIG. 4. The cooled air generated by the vortex tube 370 is directed into the second scrubbing chamber 312, while the heated air is directed away from the second scrubbing chamber 312. The cooled air lowers temperature in the second scrubbing chamber 312, which is beneficial to increase droplet size and improve capture of particulates in the second scrubbing chamber 312 prior to entering the demister 330. As such, the second scrubbing chamber 312 has lower temperature than the first and third scrubbing chambers 310, 314.

The vortex tube 370 is operable to lower temperature (or “combined temperature”) in the second scrubbing chamber 312. Namely, cooled air expelled from the vortex tube 370 into the second scrubbing chamber 312 may mix with ambient air in the second scrubbing chamber 312, thereby lowering combined temperature in the second scrubbing chamber 312. The ambient air may be at an ambient temperature in a range of about 25° C. to about 30° C. The ambient temperature may also be an operating temperature of the second scrubbing chamber 312. By lowering the combined temperature in the second scrubbing chamber 312, temperature of moisture in the second scrubbing chamber 312 may reach a dew point. For example, the temperature of the moisture (e.g., the combined temperature) may be below a saturation temperature. In some embodiments, the temperature of the moisture is in a super saturation temperature range. For example, the temperature of the moisture may be in a range of about 5° C. to about 23° C. Generally, the combined temperature is below the ambient temperature or operating temperature. To reduce the combined temperature to below the saturation temperature, such as the super saturation region, in some embodiments, the vortex tube 370 provides cooled air having temperature in a range of about −12° C. to about −40° C. when using compressed air as working fluid. The temperature of the cooled air being above about −12° C. may result in insufficient nucleation of droplets. Namely, the combined temperature may be above the saturation temperature. The temperature of the cooled air being below about −40° C. may result in ice formation and expelled ice from the vortex tube 370 or other unwanted phenomena in the second scrubbing chamber 312. The ambient air may have temperature in a range of about 25° C. to about 30° C. The combined temperature may be in a range of about 5° C. to about 23° C. The combined temperature being below about 5° C. may result in formation of ice. The combined temperature being above about 23° C. may result in insufficient nucleation of droplets.

In some embodiments, a distance between cool air output of the vortex tube 370 and the demister 330 exceeds a duct hydraulic diameter. The hydraulic diameter can refer to effective diameter of a conduit or channel through which fluid is flowing. It may be four times cross-sectional area of the conduit divided by a wetted perimeter. The wetted perimeter is a length of the conduit in contact with the fluid.

FIG. 3 depicts a single vortex tube 370 in the cleaning system 30. In some embodiments, two or more vortex tubes 370 are coupled to the second scrubbing chamber 312. This may have a benefit of improving cooling speed and responsiveness. Each of the vortex tubes 370 may be controlled individually or as a group. Controlling the vortex tubes 370 individually (e.g., independently from each other) may be beneficial to provide targeted cooling of some regions of the second scrubbing chamber 312 while cooling other regions less or not at all. As such, a cooling profile may be generated for the multiple vortex tubes 370 that improves removal of particulates by the scrubber 30.

FIG. 4 is a diagrammatic view of a vortex tube 40 in accordance with various embodiments. The vortex tube 40 may be an embodiment of the vortex tube 370 of FIG. 3.

The vortex tube 40 includes an inlet 410, a first outlet or cold air outlet 420, a second outlet or hot air outlet 430, a control valve 440 and a tube 450.

The vortex tube 40 may have a single inlet 410 through which compressed air enters. The tube 450 may be a main body where the vortex phenomenon occurs and may be or include a durable material such as stainless steel. A diaphragm or vortex generator 412 may be situated near the inlet 410 and may have a small hole that helps in initiating the vortex. The hot air outlet 430 may be at one end of the tube 450 and allows hot air 432 to escape. The cold air outlet 420 may be at the other end of the tube 450 and is where cold air 422 is emitted. The control valve 440 is located at the hot air end and can be adjusted to control volume and temperature of the exiting hot air 432, which also indirectly controls parameters of the cold air 422.

In operation, compressed air enters through the inlet 410 and is forced through the diaphragm or vortex generator 412, which initiates a high-speed vortex. The air spirals along the inner walls of the tube 450 at high speeds, creating a vortex. The air vortex moves down the tube 450 toward the control valve 440. As the vortex reaches the end with the control valve 440, two things happen: a) the inner vortex 460 loses kinetic energy and, due to adiabatic expansion, cools down; and b) the outer vortex 462 gains energy and becomes hotter. The inner, colder vortex 460 is forced to exit through the cold air outlet 420, while the outer, hotter vortex 462 escapes through the hot air outlet 430. By adjusting the control valve 440 at the hot air end 430, volume and temperature of both the hot and cold air streams 462, 460 may be adjusted.

In some embodiments, the compressed air has temperature of about 20° C., the cold air 422 has temperature in a range of about −12° C. to about −40° C., and the hot air 432 has temperature in a range of about 90° C. to about 130° C. The cold air 422 may have temperature that is as much as 60° C. lower than that of the compressed air (e.g., 20° C.−60° C.=−40° C.). In some embodiments, the cold air 422 has temperature in a range of about −12° C. to about −33° C. In some embodiments, gauge pressure of the compressed air, measured in “pounds per square inch-gauge” or “PSIG,” is in a range of about 80 PSIG to about 100 PSIG.

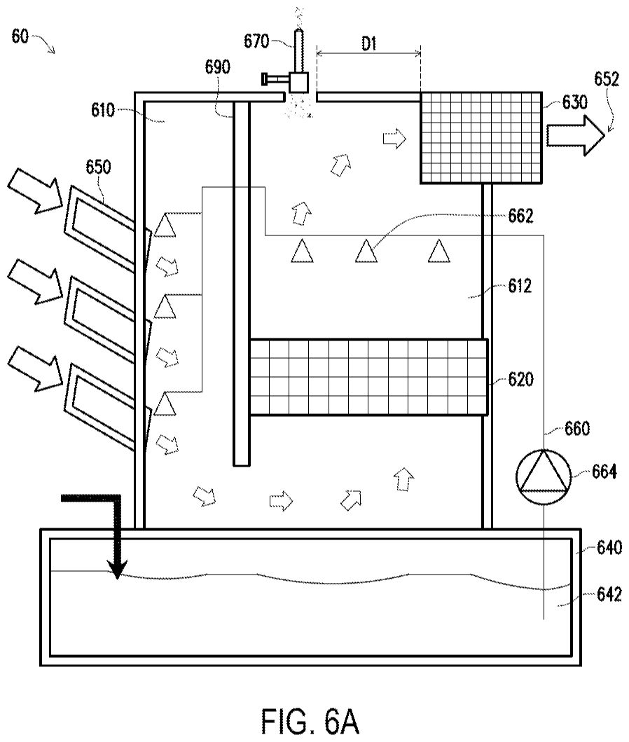

FIG. 5 is a process flow view illustrating a process 50 by which salt particulates are nucleated and captured in accordance with various embodiments. The process 50 may include fewer or additional steps or stages than depicted in FIG. 5.

In a first stage 510, initially, particulates 560 and mist droplets 570 are introduced into a space, such as the first scrubbing chamber 310 described with reference to FIG. 3. The particulates 560 may be ammonium salt particles as described with reference to FIGS. 1-3. The mist droplets 570 may be scrubbing liquid 342 expelled from the spray nozzles 362 described with reference to FIG. 3. Due to airflow of the exhaust entering the first scrubbing chamber 310 via the inlet duct 350 and motion of the scrubbing liquid 342 expelled from the spray nozzles 362 under pressure from the pump, convective interception may occur between the particulates 560 and the mist droplets 570 in the first stage 510.

In a second stage 520, the particulates 560 and the mist droplets 570 may come into contact via van der Waals attraction therebetween.

In a third stage 530, heterogenous nucleation may occur, which forms a particulate droplet 580 including the mist droplet 570 and the particulate 560.

In a fourth stage 540, growth of the particulate droplet 580 occurs in the humid environment of the first scrubbing chamber 310, the packing material 320, the second scrubbing chamber 312, or a combination thereof.

In a fifth stage 550, the larger particulate droplet 580 may contact a surface of the packing material 320 or the demister 330 due to inertial impact and/or due to diffusion to the surface via Brownian motion. In some embodiments, the surface is a surface of a fiber 590. In some embodiments, the surface is a corrugated surface or a wire mesh surface of the packing material 320 or the demister 330.

FIGS. 6A, 6B, 6C are diagrammatic views of a cleaning system 60, a structured material 62 and another structured material 62A in accordance with various embodiments.

The cleaning system 60 of FIG. 6A may be a wet-type scrubber 60 and is similar in many respects to the cleaning system 30 described with reference to FIG. 3.

The cleaning system 60 includes one or more (e.g., three) inlet ducts 650, which are similar in most respects to the inlet duct 350 described with reference to FIG. 3. The cleaning system 60 includes first and second scrubbing chambers 610, 612 which are similar in most respects to the first and second scrubbing chambers 310, 312 described with reference to FIG. 3. The cleaning system 60 includes packing material 620 and a demister 630 which are similar in most respects to the packing material 320 and demister 330, respectively, described with reference to FIG. 3. The cleaning system 60 includes a sump 640 and recirculation system 660 which are similar in most respects to the sump 340 and recirculation system 360 described with reference to FIG. 3. The sump 640 has scrubbing fluid 642 therein, which is similar in most respects to the scrubbing fluid 342 described with reference to FIG. 3. The recirculation system 660 includes a pump 664, transport lines and spray nozzles 662, which are similar to those described with reference to FIG. 3. The cleaning system 60 includes a vortex tube 670 which is similar in most respects to the vortex tubes 370, 40 described with reference to FIGS. 3 and 4, respectively.

The first scrubbing chamber 610 may be L-shaped as depicted in FIG. 6. For example, the inlet duct(s) 650 and at least one of the spray nozzles 662 may be arranged at a vertical portion of the first scrubbing chamber 610, and the packing material 620 may be arranged over a horizontal portion of the first scrubbing chamber 610. The spray nozzles 662 in the first scrubbing chamber 610 may be arranged in positions near and/or slightly above the respective inlet duct(s) 650, as depicted.

The second scrubbing chamber 612 may be disposed over the horizontal portion of the first scrubbing chamber 610 and may be separated from the vertical region of the first scrubbing chamber 610 by a wall 690. The packing material 620 may extend in the horizontal direction from the wall 690 and may separate the horizontal region of the first scrubbing chamber 610 from the second scrubbing chamber 612 along the vertical direction. The demister 630 may be positioned at a top of the cleaning system 60 adjacent an upper region of the second scrubbing chamber 612. The outlet duct 652 may be directly adjacent to the demister 630 with no third scrubbing chamber therebetween. At least one of the spray nozzles 662 may be positioned in the second scrubbing chamber 612 above the packing material 620, which may be beneficial to maintain wetting of the packing material 620 while also forming a humid environment in the second scrubbing chamber 612.

The vortex tube 670 may be arranged at the upper region of the second scrubbing chamber 612 and offset from the demister 630 by a distance D1. The distance D1 may exceed at least a duct hydraulic diameter. In some embodiments, the vortex tube 670 is nearer to the wall 690 than it is to the demister 630.

FIG. 6B is a diagrammatic view of a structured material 62, which may be the packing material 620, the demister material 630 or both, in accordance with various embodiments. The structured material 62 may include at least two sheets 622. Each of the sheets 622 may have a wave shape that forms a corrugated structure when layered or stacked with adjacent sheets 622. Interfacial area of the structured material 62 may exceed about 250 m²/m³, such as about 300 m²/m³. The structured material 62 may be or include one or more of polypropylene (PP), polyvinyl chloride (PVC), polytetrafluoroethylene (PTFE), ceramic, a glass-filled plastic (e.g., PP or PVC), or the like.

FIG. 6C is a diagrammatic view of a structured material 62A, which may be the packing material 620, the demister material 630 or both, in accordance with various embodiments. The structured material 62A may include bars 626 having wire mesh 624 wrapped there around. Each of the bars 626 may have a rectangular shape having length that extends in a Y-axis direction, width that extends in an X-axis direction and height that extends in a Z-axis direction. The bars 626 may be arranged in layers along the X-axis direction, and the layers may be stacked along the Z-axis direction. A single wire mesh sheet 624 may wrap around the bars 626 of each respective layer. Interfacial area of the structured material 62A may exceed about 250 m²/m³, such as about 300 m²/m³. The bars 626 may be or include one or more of polypropylene (PP), polyvinyl chloride (PVC), polytetrafluoroethylene (PTFE), ceramic, a glass-filled plastic (e.g., PP or PVC), or the like. The wire mesh 624 may be or include one or more materials that are resistant to, for example, sulfuric acid, such as any of the materials just mentioned or a metal material, such as nickel, chromium, molybdenum, titanium, tantalum, austenitic stainless steel, alloys thereof, combinations thereof, or the like.

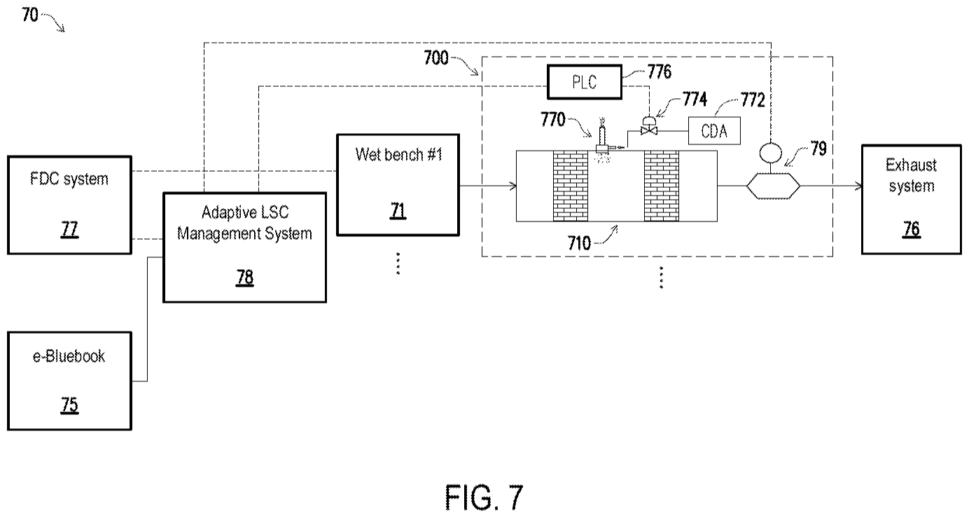

FIG. 7 is a diagrammatic view of a semiconductor processing system 70 in accordance with various embodiments. The semiconductor processing system 70 may be an embodiment of the semiconductor processing system 10 described with reference to FIG. 1 and may be similar in many respects to the semiconductor processing system 10.

The semiconductor processing system 70 includes one or more wet bench tools 71, one or more cleaning systems 700 in communication with the respective wet bench tools 71, an exhaust system 76, a fault detection (FDC) system 77, a sensor 79 and an adaptive local scrubber (LSC) management system 78. The cleaning system 700 includes a scrubber 710, a vortex tube 770 in communication with the scrubbing chamber 710, a compressed air (CDA) supply 772, a CDA valve or “compressed air control valve” 774 and a controller 776.

The wet bench tool 71 may be an embodiment of any of the wet bench tools 110, 112 described with reference to FIG. 1 and may be similar in most respects thereto. The wet bench tool 71 outputs exhaust including one or more of process gases, process byproducts, salt particulates, and the like to the cleaning system 700. For example, the scrubber 710 may receive the exhaust from the wet bench tool 71.

The scrubber 710 may be similar in most respects to the scrubbers 120, 30 and 60 described with reference to FIGS. 1, 3 and 6, respectively. The scrubber 710 receives the exhaust from the wet bench tool 71 and is operable to remove process gases, byproducts, salt particulates and the like from the exhaust to clean the exhaust prior to the exhaust being released into the atmosphere via the exhaust system 76. The exhaust system 76 may be similar in most respects to the cleaning and exhausting system 16 described with reference to FIG. 1.

The vortex tube 770 may be similar in most respects to the vortex tubes 370 and 40 described with reference to FIGS. 3 and 4. The vortex tube 770 is operable to lower temperature in the scrubber 710 to improve nucleation of particulates and increase droplet size, which are beneficial to removing the particulates from the exhaust. Temperature and/or flow rate of cold air expelled by the vortex tube 770 may be controlled via flow rate of the compressed air supply 772 connected thereto.

The CDA supply 772 may be included in the cleaning system 700 or may be external to the cleaning system 700. The CDA supply 772 supplies compressed air to the vortex tube 770. The CDA valve 774 is operable to control flow of the compressed air to the vortex tube 770. For example, the CDA valve 774 may be operable to turn on the flow, turn off the flow, constrict or limit the flow, or a combination thereof. The CDA valve 774 may be controlled electronically by the controller 776. In some embodiments, the CDA valve 774 includes an opening whose size can be controlled by the controller 776. Size of the opening may be reduced by control of the controller 776 to reduce flow rate of the compressed air or may be increased by control of the controller 776 to increase flow rate of the compressed air.

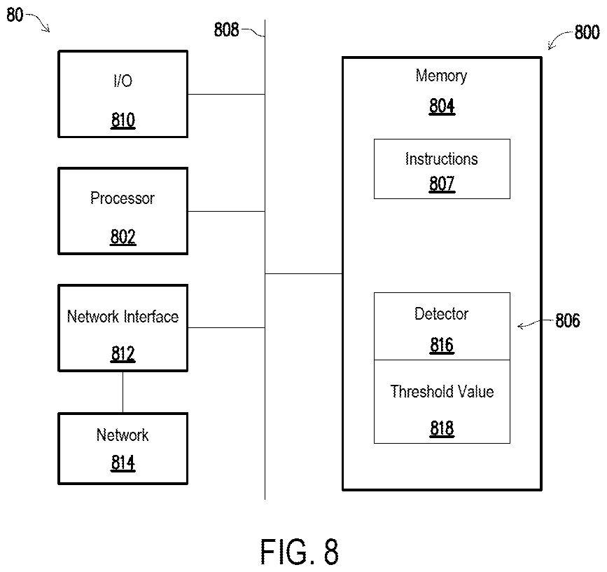

The controller 776 may be or include a programmable logic controller (PLC), microcontroller (MCU), microprocessor (MPU), another suitable controller, or the like. A controller 80 that is an embodiment of the controller 776 is described in detail with reference to FIG. 8. The controller 776 may control operation (e.g., turning on, turning off, constricting, increasing) of the CDA valve 774.

The sensor 79 may be an inline acid and/or alkaline sensor installed at a discharge location of the local scrubber 710 and may be operable to measure acid/alkaline matter and relevant ammonium salt concentration. Based on variations in the acid/alkaline matter and relevant ammonium salt concentration in the discharge, the sensor 79 may feedback a signal to the management system 78 and CDA air flow rate and/or cold air discharge temperature of vortex tube 770 may be controlled by the controller 776 based thereupon. For example, the CDA air flow rate and/or cold air discharge temperature may be selected locally or centrally, manually or remotely. In some embodiments, the sensor 79 includes a sampling tube connected to an exhaust duct of the local scrubber 710 and is operable to collect gas/particle into an instrument thereof to analyze gas/particle type and concentration and mass flowrate of pollutants. For example, the sensor 79 may generate and output a digital signal, such as a digital value, that is associated with concentration and/or mass flowrate of the ammonium salt particles in the exhaust of the local scrubber 710.

In some embodiments, the controller 776 may receive a valve setting associated with a flow rate and/or cold air discharge temperature directly from the management system 78 and control the CDA valve 774 based on the valve setting. In some embodiments, the controller 776 may receive a selected flow rate and/or selected cold air discharge temperature from the management system 78, calculate the valve setting, then control the CDA valve 774 based on the valve setting. In some embodiments, the valve setting, the flow rate and/or the cold air discharge temperature is selected by a human operator instead of being selected autonomously.

The management system 78 is in electrical and/or data communication with the FDC system 77, the controller 776 and the sensor 79. In some embodiments, the management system 78 collects tool status data from the FDC system 77 and/or an electronic bluebook (or “e-bluebook”) 75, and determines an opening of the CDA valve 774 into the vortex tube 770 according to quantity of wafer throughput and/or chemical consumption of the wet bench tool 71. The management system 78 may compare the data from the FDC system 77 and/or e-bluebook 75 with data (e.g., the digital value) received from the acid/alkaline sensor 79. In some embodiments, the flow rate and/or temperature of the cold air expelled into the local scrubber 710 may be determined autonomously according to an algorithm stored in the management system 78 and the data from the FDC system 77, the e-bluebook 75 and/or the sensor 79. In some embodiments, the management system 78 is similar in most respects to the controller 80 described with reference to FIG. 8.

The FDC system 77 may be similar in most respects to the controller 80 described with reference to FIG. 8. In some embodiments, the FDC system 77 stores tool status data, such as wafer throughput data and/or chemical consumption data of the wet bench tool 71. The FDC system 77 may be operable to perform real-time monitoring of the wet bench tool 71 used for etching, cleaning, or other chemical processes, which may be equipped with one or more sensors that monitor factors, such as temperature, flow rate and chemical concentration. The FDC system 77 can continuously monitor these parameters. The FDC system 77 may be operable to perform anomaly detection, such as when a parameter goes outside of its selected range. The FDC system 77 can generate a report or alarm associated with the anomaly for attention by another system or a human operator, which is beneficial for processes involving corrosive or hazardous chemicals, where deviations can lead to safety issues or material defects. By analyzing historical data, the FDC system 77 may be operable to predict when the wet bench tool 71 or a component thereof is likely to fail, such that preventive action may be taken. The FDC system 77 may be integrated with one or more data-logging systems, such as a database, to generate a record of events, which may be beneficial for troubleshooting and quality assurance.

The e-bluebook 75 or “electronic bluebook” 75 may be or include a digital record-keeping system that logs process steps, parameters, operator actions, and any deviations or issues. Information from the FDC system 77 can be integrated into the e-bluebook 75, generating a comprehensive record that correlates equipment performance and process parameters. The e-bluebook 75 may be beneficial to simplify tracing back the cause of any defects or yield issues, especially those related to a process at the wet bench tool 71. Both the FDC system 77 and the electronic bluebook 75 may be beneficial for maintaining compliance with quality standards and regulations and may also serve as beneficial tools during internal or external audits.

Although depicted in FIG. 7 as being in direct data communication with the management system 78, in some embodiments, the management system 78 accesses data generated by the FDC system 77 and/or the e-bluebook 75 via a database that stores the data. Namely, the FDC system 77 and/or the e-bluebook 75 may each store data in a single database or in separate databases, and the management system 78 may retrieve the data of each from the database or databases.

FIG. 8 is a schematic view of a controller 80 in accordance with various embodiments. The controller 80 may be an embodiment of the controller 776, the management system 78, the FDC system 77, the e-bluebook 75, or a combination thereof.

In FIG. 8, the controller or control system 80 includes a processor 802, a memory 800, a data interface 810 and a network interface 812. Some elements of the controller 80 may be omitted from view for simplicity of illustration. For example, the controller 80 may include a power supply (e.g., voltage regulator), analog-to-digital converters (ADCs), digital-to-analog converters (DACs), pulse width modulation (PWM) controller, clocks and timing circuitry, and the like.

The control system 80 generates output control signals for controlling operation of one or more components of the semiconductor processing systems 10, 70. The control system 80 may receive input signals from one or more components of the systems 10, 70. In some embodiments, the control system 80 is located adjacent the systems 10, 70, remote from the systems 10, 70 or in the systems 10, 70. The controller 80 may be an embodiment of the controller 776, the management system 78, the FDC system 77, the e-bluebook 75, or a combination thereof.

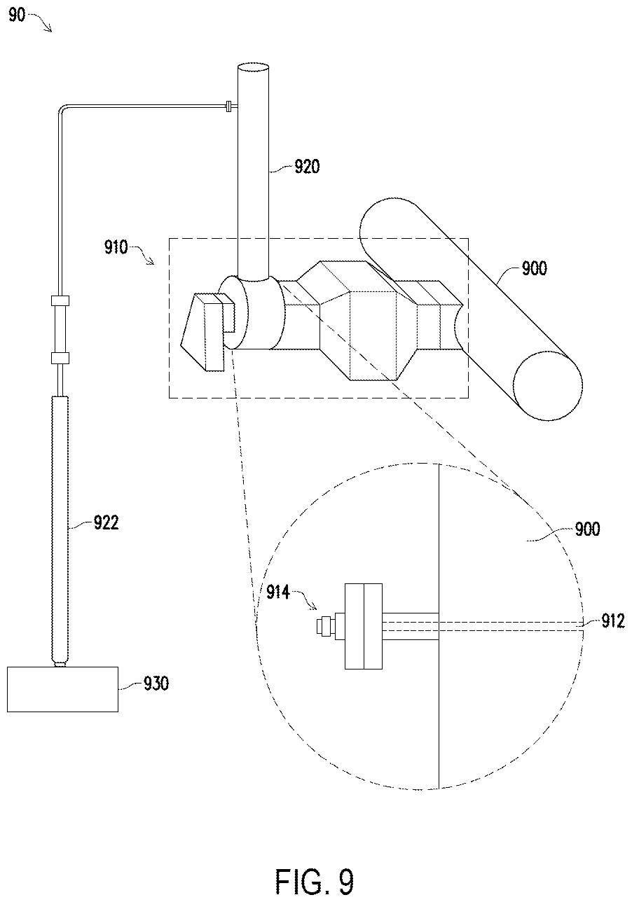

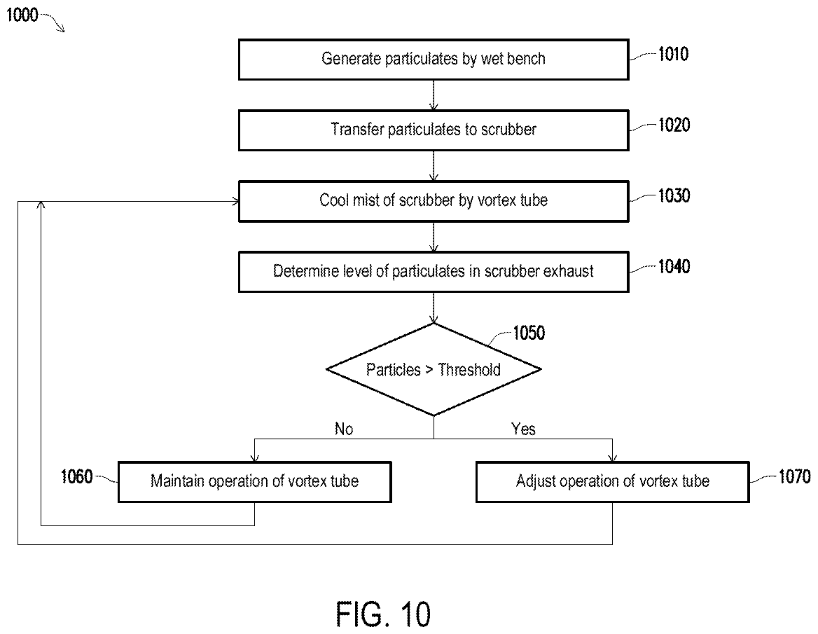

Control system 80 includes a processor 802 and a non-transitory, computer readable storage medium 804 encoded with, i.e., storing, computer program code 806, i.e., a set of executable instructions. Computer readable storage medium 804 is also encoded with instructions 807 for interfacing with components of apparatus 10. The processor 802 is electrically coupled to the computer readable storage medium 804 via a bus 808. The processor 802 is also electrically coupled to an I/O interface 810 by bus 808. A network interface 812 is also electrically connected to the processor 802 via bus 808. Network interface 812 is connected to a network 814, so that processor 802 and computer readable storage medium 804 are capable of connecting to external elements via network 814. The processor 802 is configured to execute the computer program code 806 encoded in the computer readable storage medium 804 in order to cause control system 80 to be usable for performing a portion or all of the operations as described with respect to systems 10, 70, including those that will be described with reference to FIGS. 9 and 10 below.

In some embodiments, the processor 802 is a central processing unit (CPU), a multi-processor, a distributed processing system, an application specific integrated circuit (ASIC), and/or a suitable processing unit.

In some embodiments, the computer readable storage medium 804 is an electronic, magnetic, optical, electromagnetic, infrared, and/or a semiconductor system (or apparatus or device). For example, the computer readable storage medium 804 includes a semiconductor or solid-state memory, a magnetic tape, a removable computer diskette, a random access memory (RAM), a read-only memory (ROM), a rigid magnetic disk, and/or an optical disk. In some embodiments using optical disks, the computer readable storage medium 804 includes a compact disk-read only memory (CD-ROM), a compact disk-read/write (CD-R/W), and/or a digital video disc (DVD).

In some embodiments, the storage medium 804 stores the computer program code 806 configured to cause control system 80 to perform the operations as described with respect to apparatus 10, 70. In some embodiments, the storage medium 804 also stores information needed for performing the operations as described with respect to apparatus 10, 70, such as a particle parameter 816, a threshold value parameter 818, and/or a set of executable instructions to perform the operations as described with respect to apparatus 10, 70.

In some embodiments, the storage medium 804 stores instructions 807 for interfacing with apparatus 10, 70 (e.g., sensor 79, FDC system 77, e-bluebook 75, controller 776 and the like). The instructions 807 enable processor 802 to generate operating instructions readable by elements of the apparatus 10, 70 to effectively implement the operations as described with respect to apparatus 10, 70.

Control system 80 includes I/O interface 810. I/O interface 810 is coupled to external circuitry. In some embodiments, I/O interface 810 includes a keyboard, keypad, mouse, trackball, trackpad, and/or cursor direction keys for communicating information and commands to processor 802.

Control system 80 also includes network interface 812 coupled to the processor 802. Network interface 812 allows control system 80 to communicate with network 814, to which one or more other computer systems are connected. Network interface 812 includes wireless network interfaces such as BLUETOOTH, WIFI, WIMAX, GPRS, or WCDMA; or wired network interface such as ETHERNET, USB, or IEEE-1394.

Control system 80 is configured to receive information related to the sensor 70 through I/O interface 810. The information is transferred to processor 802 via bus 808 and then stored in computer readable medium 804 as particle parameter 816. Control system 80 is configured to receive information related to the threshold value through I/O interface 810. In some embodiments, the threshold value is received from an operator. The information is stored in computer readable medium 804 as threshold value parameter 818.

During operation, in some embodiments, processor 802 executes a set of instructions to determine whether the particle parameter has exceeded a threshold value. Based on the above determinations, processor 802 generates a control signal to instruct the controller 776 to adjust flow of compressed air into the vortex tube 770. In some embodiments, the processor 802 may generate a second control signal to instruct the controller 776 to adjust a control valve (e.g., the control valve 440) of the vortex tube 770, which may adjust temperature of cold air expelled from the vortex tube 770 into the scrubber 710. In some embodiments, the control signal is transmitted using I/O interface 810. In some embodiments, the control signal is transmitted using network interface 812.

FIG. 9 is a diagrammatic view of a sampling system 90 in accordance with various embodiments. The sampling system 90 may be an embodiment of the sensor 79 described with reference to FIG. 7.

The sampling system 90 may include a sampling assembly 910 that is in fluid communication with an exhaust tube 900 of a scrubber (e.g., the scrubber 120 or the scrubber 710). The sampling system 90 may include a first transport line 920 in fluid communication with the sampling assembly 910 and a second transport line 922 in fluid communication with the first transport line 920. The sampling system 90 may include an analyzer 930 in fluid communication with the second transport line 922. In some embodiments, the second transport line 922 is omitted, and a single transport line 920 is in fluid communication with the sampling assembly 910 and the analyzer 930.

The sampling assembly 910 may include a sampling needle 912 that penetrates a wall of the exhaust tube 900. The sampling assembly 910 may include a valve 914 that is in fluid communication with the sampling needle 912 and the first transport line 920. The valve 914 may be opened to draw exhaust of the scrubber into the analyzer 930 from the exhaust tube 900 and via the first and/or second transport line(s) 920, 922.

The analyzer 930 may be operable to determine gas/particle type in the collected exhaust, to determine gas/particle concentration of the collected exhaust, and/or to determine a mass flowrate of gases and/or particulates in the collected exhaust. For example, the analyzer 930 may include a spectrum analyzer, such as a mass spectrometer. The analyzer 930 may store real-time values and/or historical data of gas/particle type, gas/particle concentration and/or mass flowrate. The real-time values and/or historical data may be outputted to a controller, such as the management system 78 described with reference to FIG. 7.

FIG. 10 is a flowchart of a method 1000 of performing semiconductor processing in accordance with various embodiments. The acts illustrated in FIG. 10 may be performed in accordance with the systems 10, 70 described with reference to FIGS. 1-9. FIG. 10 illustrates a flowchart of method 1000 for processing a semiconductor device according to one or more aspects of the present disclosure. Method 1000 is an example and is not intended to limit the present disclosure to what is explicitly illustrated in method 1000. Additional acts can be provided before, during and after the method 1000 and some acts described can be replaced, eliminated, or moved around for additional embodiments of the methods. For example, the method 1000 may be used for etching and/or cleaning a wafer. Not all acts are described herein in detail for reasons of simplicity. For example, acts for loading and/or removing the wafer(s) from a wet bench tool are not described in the method 1000, but may be performed as part of the method 1000. Similarly, acts that follow the acts of method 1000, for example, that are related to deposition and/or epitaxial growth of device features on the wafer(s) are also omitted from view and not described in detail herein. Acts of method 1000 are described below with reference to elements of the systems 10, 70 of FIGS. 1-9. Many of the acts may be performed by the controller 80 (e.g., the management system 78 and/or the controller 776). For example, the controller 80 may execute instructions to perform the acts of method 1000. It should be understood that the method 1000 is not limited to being performed by the systems 10, 70 and/or the controller 80, and may be performed by systems that differ in one or more respects from the systems 10, 70 and/or controller 80 in other embodiments.

In FIG. 10, the method 1000 begins with act 1010, which includes generating particulates by a wet bench tool. For example, the exhausted process gases may be flowed to an inlet duct of a scrubber via a transport line coupled to an exhaust port of the wet bench tool. The particulates may be generated when exhausted process gases react in the exhaust port and/or the transport line. For example, the particulates may include ammonium salt particulates generated as a result of process gases from an SPM process and an APM process mixing in the exhaust port and/or transport line, as described with reference to FIG. 2. The SPM process and APM process may be a cleaning process performed on a wafer undergoing semiconductor processing to form integrated circuit (IC) dies on and/or in the wafer.

Act 1020 follows act 1010. In act 1020, the particulates are transferred to the scrubber. For example, the particulates may enter the first scrubbing chamber 610 of the scrubber 60 via the input duct 650 as part of the exhaust transported from the wet bench tool.

Act 1030 follows act 1020. In act 1030, mist of the scrubber is cooled by a vortex tube. For example, the vortex tube 670 cools mist in the second scrubbing chamber 612. The cooling via the vortex tube can improve capture of the particulates by mist droplets in the second scrubbing chamber 612. Act 1030 may be performed via a single vortex tube or two or more vortex tubes. Prior to entering the second scrubbing chamber, the particulates may pass through the structured packing material 620 described with reference to FIG. 6. This may improve removal of process gases and particulates already captured by mist droplets prior to the particulates entering the second scrubbing chamber. Following passage through the second scrubbing chamber having lower temperature than the first scrubbing chamber, the particulates may be nucleated in mist droplets. Then, the mist droplets may pass into the demister 630, which has increased surface area and is structured, which may increase a rate at which the mist droplets attach to the demister 630 and are eventually removed into the sump 640.

Act 1040 follows act 1030. In act 1040, following passage of the exhaust including the mist droplets through the demister, exhaust exiting the scrubber (or “scrubber exhaust”) is analyzed to determine a level of particulates in the scrubber exhaust. The scrubber exhaust may be analyzed, for example, by the sensor 79, such as by the analyzer 930 described with reference to FIG. 9. The analysis may determine type and concentration of gases/particulates in the scrubber exhaust and/or mass flowrate of the particulates. For example, a count of the particles associated with an interval of time or “particulate mass flowrate” may be generated by the analyzer 930. A result of the detection may be referred to as a “particle parameter,” which may be an embodiment of the particle parameter 816 of FIG. 8.

Act 1050 follows act 1040. In act 1050, following generating the particle parameter in act 1040, a determination may be made whether the particle parameter exceeds a threshold value (e.g., the threshold value 818 of FIG. 8). The threshold value may correspond to the particle parameter. For example, the particle parameter may be a measured mass flowrate of particulates and the threshold value may be a selected mass flowrate of the particulates. A comparison may be made between the measured mass flowrate and the selected mass flowrate. In another example, the particle parameter may be a measured concentration of particulates and the threshold value may be a selected concentration of the particulates.

In response to the particle parameter not exceeding the threshold value, the method 1000 may continue to act 1030 via act 1060, in which operation of the vortex tube is maintained. For example, the vortex tube may operate with an associated flow rate of compressed air and an associated opening size of the control valve (e.g., the compressed air control valve 774 or the control valve 440). The flow rate and/or opening size may be unchanged when act 1060 of the method 1000 is performed. Namely, the flow rate and/or opening size may be the same prior to act 1050 as after act 1050 when the particle parameter does not exceed the threshold value.

In response to the particle parameter exceeding the threshold value, the method 1000 may proceed to act 1030 via act 1070. In act 1070, which follows act 1050, flow rate of the compressed air and/or opening size of the control valve is adjusted based on the particle parameter exceeding the threshold value. For example, when the particle parameter exceeds the threshold value, this may indicate that the temperature in the second scrubbing chamber is not sufficiently low to achieve a selected efficiency of particulate removal from the exhaust of the wet bench tool as measured from the scrubber exhaust. As such, the flow rate and/or temperature of the vortex tube may be adjusted.

In some embodiments, in act 1070, adjusting the flow rate of the cold air of the vortex tube includes increasing the flow rate of the compressed air. The flow rate of the compressed air may be increased by a selected amount, e.g., 10%, 20%, or other suitable amount. The flow rate may be increased proportional to difference between the particle parameter and the threshold value. For example, a larger difference between the particle parameter and the threshold value may result in a larger increase in the flow rate and a smaller difference between the particle parameter and the threshold value may result in a smaller increase in the flow rate.

In some embodiments, in act 1070, adjusting the temperature of the cold air of the vortex tube to reduce temperature of the cold air includes decreasing the opening size of the control valve. The opening size may be decreased by a selected amount, e.g., 10%, 20%, or other suitable amount. The opening size may be decreased proportional to difference between the particle parameter and the threshold value. For example, a larger difference between the particle parameter and the threshold value may result in a larger reduction in the opening size and a smaller difference between the particle parameter and the threshold value may result in a smaller reduction in the opening size.

Additional acts may follow acts 1060 and 1070. For example, the wafer may be removed from the wet bench tool following completion of the cleaning or etching process. Then, additional operations to form other layers on the wafer may be performed.

By adjusting the vortex tube cold air output dynamically in response to level of particles in the scrubber exhaust, the method 1000 may reduce particles that are exhausted into the atmosphere, which may reduce tool downtime.

Embodiments may provide advantages. Cleaning systems having the structured packing, structured demister, vortex tube and control system can have increased ammonium salt particulate removal, which can prolong intervals between preventative maintenance and reduce tool downtime.

In accordance with at least one embodiment, a method includes: processing a wafer by a wet bench apparatus; forming particulates in an exhaust of the wet bench apparatus; flowing the exhaust to a first scrubbing chamber of a scrubber; removing a first portion of the particulates from the exhaust by flowing the exhaust to a second scrubbing chamber via a structured packing material; cooling the second scrubbing chamber by a vortex tube; and removing a second portion of the particulates from the exhaust by a structured demister adjacent the second scrubbing chamber.

In accordance with at least one embodiment, a method includes: forming exhaust including particulates by a wet bench apparatus; flowing the exhaust to a scrubber; cooling mist of the scrubber by a vortex tube; determining a level of the particulates in scrubber exhaust exiting the scrubber by a sensor; determining whether the level exceeds a threshold value; and in response to the level exceeding the threshold value, adjusting operation of the vortex tube.

In accordance with at least one embodiment, a system includes: a wet bench apparatus; a scrubber in fluid communication with the wet bench apparatus, the scrubber including: a first scrubbing chamber; a second scrubbing chamber having temperature lower than that of the first scrubbing chamber; a packing material between the first scrubbing chamber and the second scrubbing chamber; an outlet duct; and a demister between the second scrubbing chamber and the outlet duct; a sensor operable to determine a level of particulates in scrubber exhaust exhausted from the scrubber; and a controller operable to adjust the temperature of the second scrubbing chamber based on the level of particulates in the scrubber exhaust.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
processing a wafer by a wet bench apparatus;
forming particulates in an exhaust of the wet bench apparatus;
flowing the exhaust to a first scrubbing chamber of a scrubber;
removing a first portion of the particulates from the exhaust by flowing the exhaust to a second scrubbing chamber via a structured packing material;
cooling the second scrubbing chamber by a vortex tube; and
removing a second portion of the particulates from the exhaust by a structured demister adjacent the second scrubbing chamber.

2. The method of claim 1, wherein the removing the first portion includes flowing the exhaust through the structured packing material including a corrugated material or wire mesh, the structured packing material having interfacial area exceeding about 250 m²/m³.

3. The method of claim 1, wherein the removing a second portion includes flowing the exhaust through the structured demister including a corrugated material or wire mesh, the structure demister having interfacial area exceeding about 250 m²/m³.

4. The method of claim 1, wherein the cooling the second scrubbing chamber includes cooling the second scrubbing chamber by the vortex tube that outputs cooled air into the second scrubbing chamber, the cooled air having first temperature in a range of about-40° C. to about-12° C.

5. The method of claim 1, wherein the cooling the second scrubbing chamber includes cooling the second scrubbing chamber to a combined temperature that is in a range of about 5° C. to about 23° C.

6. The method of claim 1, wherein ambient air inside the second scrubbing chamber has operating temperature in a range of about 25° C. to about 30° C.

7. The method of claim 1, wherein the removing a first portion of the particulates includes removing a first portion of ammonium salt particulates.

8. A method comprising:
forming exhaust including particulates by a wet bench apparatus;
flowing the exhaust to a scrubber;
cooling mist of the scrubber by a vortex tube;
determining a level of the particulates in scrubber exhaust exiting the scrubber by a sensor;
determining whether the level exceeds a threshold value; and
in response to the level exceeding the threshold value, adjusting operation of the vortex tube.

9. The method of claim 8, wherein the adjusting includes reducing a temperature of cold air expelled by the vortex tube.

10. The method of claim 8, wherein the adjusting includes increasing a flow rate of cold air expelled by the vortex tube.

11. The method of claim 8, wherein the adjusting includes increasing an opening size of a compressed air control valve by a controller.

12. The method of claim 8, wherein the adjusting includes reducing an opening size of a control valve of the vortex tube by a controller.

13. The method of claim 8, further comprising in response to the level not exceeding the threshold value, using a same flow rate of compressed air and a same opening size of a control valve of the vortex tube as used during the cooling mist of the scrubber.

14. The method of claim 8, wherein the adjusting includes:
obtaining a wafer throughput data and a chemical consumption data from a fault detection system in data communication with the wet bench apparatus, the obtaining being by a management system;
comparing the wafer throughput data and the chemical consumption data with sensor data generated by the sensor, the comparing being by the management system; and
adjusting cold air output of the vortex tube based on an algorithm stored in the management system.

15. A system, comprising:
a wet bench apparatus;
a scrubber in fluid communication with the wet bench apparatus, the scrubber including:
a first scrubbing chamber;
a second scrubbing chamber having temperature lower than that of the first scrubbing chamber;
a packing material between the first scrubbing chamber and the second scrubbing chamber;
an outlet duct; and
a demister between the second scrubbing chamber and the outlet duct;
a sensor operable to determine a level of particulates in scrubber exhaust exhausted from the scrubber; and
a controller operable to adjust the temperature of the second scrubbing chamber based on the level of particulates in the scrubber exhaust.

16. The system of claim 15, wherein the scrubber includes a vortex tube and the controller is operable to adjust the temperature of the second scrubbing chamber by adjusting operation of the vortex tube.

17. The system of claim 16, wherein the controller is operable to reduce temperature of cold air expelled by the vortex tube when the level of particulates exceeds a threshold value.

18. The system of claim 16, wherein the controller is operable to increase flow rate of cold air expelled by the vortex tube when the level of particulates exceeds a threshold value.

19. The system of claim 18, wherein interfacial area of the packing material, the demister, or both exceeds about 250 m²/m³.

20. The system of claim 19, wherein the packing material, the demister, or both includes a corrugated material or a wire mesh material.
